(19) United States
(12) Patent Application Publication
(10) Pub. No.: US 2023/0161934 A1
(43) Pub. Date: May 25, 2023

(54) DATA MODEL BASED SIMULATION UTILIZING DIGITAL TWIN REPLICAS

(71) Applicant: International Business Machines Corporation, Armonk, NY (US)

(72) Inventors: Balaji Ganesan, Bengaluru (IN); Soma Shekar Naganna, Bangalore (IN); Pranay Kumar Lohia, Bhagalpur (IN); Priyanka Telang, Bengaluru (IN); Sameep Mehta, Bangalore (IN)

(21) Appl. No.: 17/531,857

(22) Filed: Nov. 22, 2021

(51) Int. Cl. G06F 30/27; G06N 3/08; G06N 3/04; G06K 9/62

(52) U.S. Cl. CPC G06F 30/27; G06K 9/6288; G06K 9/6296; G06N 3/04; G06N 3/08

(57) ABSTRACT

Computer hardware and/or software that perform the following operations: (i) receiving a data model, the data model including nodes representing types of information and edges representing relationships between the types of information; (ii) generating a set of digital twin replicas, where a digital twin replica of the set of digital twin replicas corresponds to a respective node of the data model; (iii) utilizing the set of digital twin replicas to generate simulated data corresponding to the types of information represented by the nodes of the data model; and (iv) combining the simulated data generated by the set of digital twin replicas into a combined set of simulated data based, at least in part, on the edges of the data model.

### BACKGROUND

The present invention relates generally to the field of data modelling, and more particularly to the simulating of data corresponding to a data model utilizing a plurality of digital twin replicas.

Generally speaking, a data model is a digitized model that organizes elements of data and standardizes how they relate to one another, commonly depicting data elements as nodes and depicting relationships between the data elements as edges. Data models can be used in a wide variety of applications, including, for example, to represent data within an organization’s Master Data Management (MDM) system.

A digital twin (also referred to as a “digital twin replica”) is a digital representation of an object or process. Digital twins are often used to simulate the effects of various stimuli and/or inputs on an object without having to actually apply the stimuli and/or inputs to the “real-world” version of the object.

### SUMMARY

According to an aspect of the present invention, there is a method, computer program product and/or system that performs the following operations (not necessarily in the following order): (i) receiving a data model, the data model including nodes representing types of information and edges representing relationships between the types of information; (ii) generating a set of digital twin replicas, where a digital twin replica of the set of digital twin replicas corresponds to a respective node of the data model; (iii) utilizing the set of digital twin replicas to generate simulated data corresponding to the types of information represented by the nodes of the data model; and (iv) combining the simulated data generated by the set of digital twin replicas into a combined set of simulated data based, at least in part, on the edges of the data model.

### BRIEF DESCRIPTION OF THE DRAWINGS

FIG. 1 is a block diagram view of a first embodiment of a system according to the present invention;

FIG. 2 is a flowchart showing a first embodiment method performed, at least in part, by the first embodiment system;

FIG. 3 is a block diagram showing a machine logic (for example, software) portion of the first embodiment system;

FIG. 4A is a diagram depicting a data model utilized by the first embodiment system;

FIG. 4B is a table view depicting output formats for digital twin replicas generated by the first embodiment system;

FIG. 5 is a diagram depicting an ontology utilized by an embodiment of the present invention;

FIG. 6 is a diagram depicting additional details with respect to the ontology depicted in FIG. 5, according to an embodiment of the present invention;

FIG. 7 depicts an example of a simple neural network constructed according to an embodiment of the present invention; and

FIG. 8 depicts another example of a neural network constructed according to an embodiment of the present invention.

### DETAILED DESCRIPTION

Data management systems, such as Master Data Management (MDM) systems, that organize large amounts of data for organizations often rely on data models that provide underlying definitions and relationships between types of data. However, when a dataset is incomplete, it can be difficult - for technical and often business or legal reasons - to merge the dataset with enterprise data that doesn’t already reside within the data management system. Various embodiments of the present invention generate digital twin replicas based on the data models underlying such systems, utilizing the digital twin replicas to generate simulated data corresponding to the missing parts of a dataset. Various embodiments of the present further utilize the data models to validate and combine the simulated data such that the combined set of simulated data can be merged with the original dataset to create a complete dataset for utilization across an organization.

This Detailed Description section is divided into the following sub-sections: (i) The Hardware and Software Environment; (ii) Example Embodiment; (iii) Further Comments and/or Embodiments; and (iv) Definitions.

### I. The Hardware and Software Environment

The present invention may be a system, a method, and/or a computer program product. The computer program product may include a computer readable storage medium (or media) having computer readable program instructions thereon for causing a processor to carry out aspects of the present invention.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present invention may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user’s computer, partly on the user’s computer, as a stand-alone software package, partly on the user’s computer and partly on a remote computer or entirely on the remote computer or server. In the latter scenario, the remote computer may be connected to the user’s computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present invention.

Aspects of the present invention are described herein with reference to flowchart illustrations and/or block diagrams of methods, apparatus (systems), and computer program products according to embodiments of the invention. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

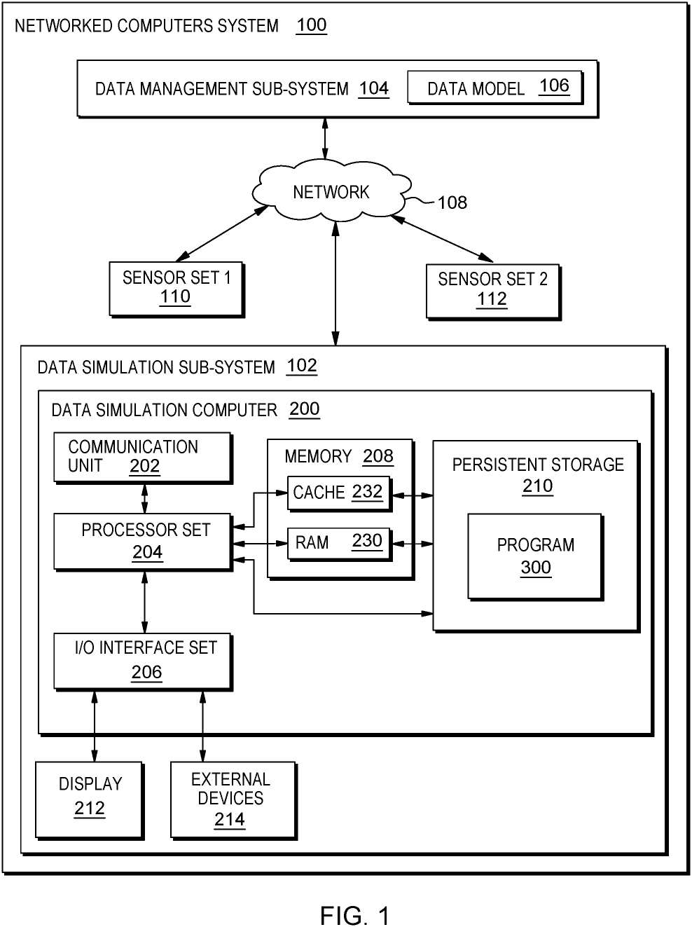

An embodiment of a possible hardware and software environment for software and/or methods according to the present invention will now be described in detail with reference to the Figures. FIG. 1 is a functional block diagram illustrating various portions of networked computers system 100, including: data simulation sub-system 102; data management sub-system 104, including data model 106; communication network 108; sensor set 1 110; sensor set 2 112; data simulation computer 200; communication unit 202; processor set 204; input/output (I/O) interface set 206; memory device 208; persistent storage device 210; display device 212; external device set 214; random access memory (RAM) devices 230; cache memory device 232; and program 300.

Sensor set 1 110 and sensor set 2 112 include respective sets of sensors configured to monitor various aspects of an enterprise’s physical operations, as will be discussed in further detail in the Example Embodiment sub-section of this Detailed Description section.

Sub-system 102 is, in many respects, representative of the various computer sub-system(s) in the present invention. Accordingly, several portions of sub-system 102 will now be discussed in the following paragraphs.

Sub-system 102 may be a laptop computer, tablet computer, netbook computer, personal computer (PC), a desktop computer, a personal digital assistant (PDA), a smart phone, or any programmable electronic device capable of communicating with the client sub-systems via network 108. Program 300 is a collection of machine readable instructions and/or data that is used to create, manage and control certain software functions that will be discussed in detail, below, in the Example Embodiment sub-section of this Detailed Description section.

Sub-system 102 is capable of communicating with other computer sub-systems via network 108. Network 108 can be, for example, a local area network (LAN), a wide area network (WAN) such as the Internet, or a combination of the two, and can include wired, wireless, or fiber optic connections. In general, network 108 can be any combination of connections and protocols that will support communications between server and client sub-systems.

Sub-system 102 is shown as a block diagram with many double arrows. These double arrows (no separate reference numerals) represent a communications fabric, which provides communications between various components of sub-system 102. This communications fabric can be implemented with any architecture designed for passing data and/or control information between processors (such as microprocessors, communications and network processors, etc.), system memory, peripheral devices, and any other hardware components within a system. For example, the communications fabric can be implemented, at least in part, with one or more buses.

Memory 208 and persistent storage 210 are computer-readable storage media. In general, memory 208 can include any suitable volatile or non-volatile computer-readable storage media. It is further noted that, now and/or in the near future: (i) external device(s) 214 may be able to supply, some or all, memory for sub-system 102; and/or (ii) devices external to sub-system 102 may be able to provide memory for sub-system 102.

Program 300 is stored in persistent storage 210 for access and/or execution by one or more of the respective computer processors 204, usually through one or more memories of memory 208. Persistent storage 210: (i) is at least more persistent than a signal in transit; (ii) stores the program (including its soft logic and/or data), on a tangible medium (such as magnetic or optical domains); and (iii) is substantially less persistent than permanent storage. Alternatively, data storage may be more persistent and/or permanent than the type of storage provided by persistent storage 210.

Program 300 may include both machine readable and performable instructions and/or substantive data (that is, the type of data stored in a database). In this particular embodiment, persistent storage 210 includes a magnetic hard disk drive. To name some possible variations, persistent storage 210 may include a solid state hard drive, a semiconductor storage device, read-only memory (ROM), erasable programmable read-only memory (EPROM), flash memory, or any other computer-readable storage media that is capable of storing program instructions or digital information.

The media used by persistent storage 210 may also be removable. For example, a removable hard drive may be used for persistent storage 210. Other examples include optical and magnetic disks, thumb drives, and smart cards that are inserted into a drive for transfer onto another computer-readable storage medium that is also part of persistent storage 210.

Communications unit 202, in these examples, provides for communications with other data processing systems or devices external to sub-system 102. In these examples, communications unit 202 includes one or more network interface cards. Communications unit 202 may provide communications through the use of either or both physical and wireless communications links. Any software modules discussed herein may be downloaded to a persistent storage device (such as persistent storage device 210) through a communications unit (such as communications unit 202).

I/O interface set 206 allows for input and output of data with other devices that may be connected locally in data communication with data simulation computer 200. For example, I/O interface set 206 provides a connection to external device set 214. External device set 214 will typically include devices such as a keyboard, keypad, a touch screen, and/or some other suitable input device. External device set 214 can also include portable computer-readable storage media such as, for example, thumb drives, portable optical or magnetic disks, and memory cards. Software and data used to practice embodiments of the present invention, for example, program 300, can be stored on such portable computer-readable storage media. In these embodiments the relevant software may (or may not) be loaded, in whole or in part, onto persistent storage device 210 via I/O interface set 206. I/O interface set 206 also connects in data communication with display device 212.

Display device 212 provides a mechanism to display data to a user and may be, for example, a computer monitor or a smart phone display screen.

The programs described herein are identified based upon the application for which they are implemented in a specific embodiment of the invention. However, it should be appreciated that any particular program nomenclature herein is used merely for convenience, and thus the invention should not be limited to use solely in any specific application identified and/or implied by such nomenclature.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

### II. Example Embodiment

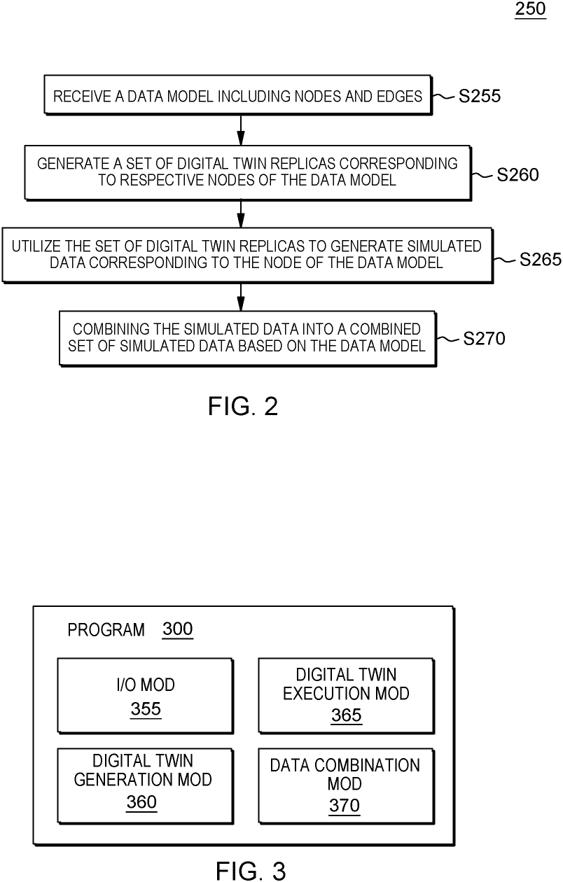

FIG. 2 shows flowchart 250 depicting a method according to the present invention. FIG. 3 shows program 300 for performing at least some of the method operations of flowchart 250. This method and associated software will now be discussed, over the course of the following paragraphs, with extensive reference to FIG. 2 (for the method operation blocks) and FIG. 3 (for the software blocks).

Generally speaking, in this example embodiment (also referred to in this sub-section as the “present embodiment,” the “present example,” the “present example embodiment,” and the like), program 300 includes various operations performed by processors 204 to generate and combine simulated data sets, based on a data model, utilizing digital twin replicas. It should be noted that this example embodiment is used herein for example purposes, in order to help depict the scope of the present invention. As such, other embodiments (such as embodiments discussed in the Further Comments and/or Embodiments sub-section, below) may be configured in different ways or refer to other features, advantages, and/or characteristics not fully discussed in this sub-section.

In the present example embodiment, networked computers system 100 is part of an enterprise Internet-of-Things (IoT) management system, where pluralities of IoT devices for an organization are managed by data management sub-system 104. Sensor set 1 110 and sensor set 2 112 include respective sets of sensors configured to monitor various aspects of the organization’s physical operations, specifically: (i) sensor set 1 110 includes sensors that are affixed to an industrial fan located in a small room located in a data center owned by the organization, and (ii) sensor set 2 112 includes sensors that are affixed to a light figure located in the same physical room as the industrial fan. For various reasons, an administrator of data management sub-system 104 wishes to simulate data produced by sensor set 1 110 and sensor set 2 112, and as such the administrator sends a simulation request to data simulation sub-system 102, which includes data simulation computer 200 and program 300, to perform various data simulation operations as will now be discussed.

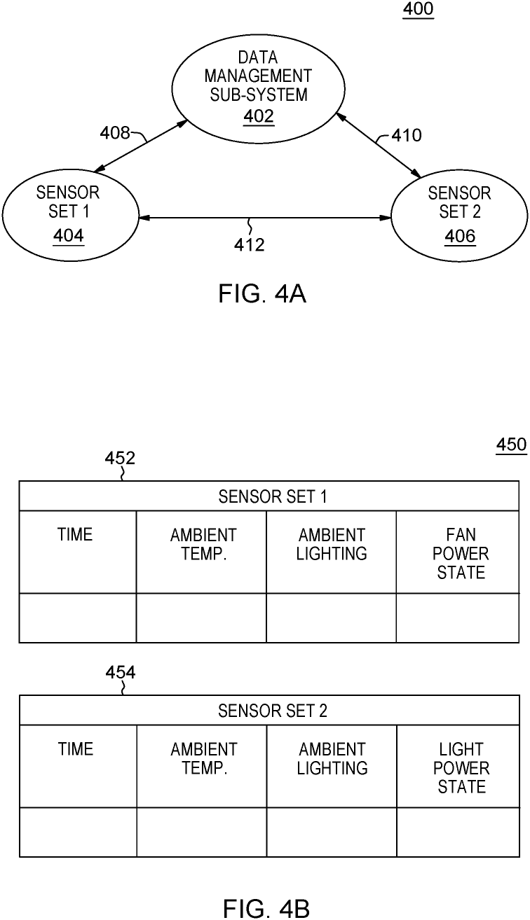

Processing begins at operation S255, where I/O module (“mod”) 355 receives data model 106 from data management sub-system 104. FIG. 4A is a diagram depicting specific details of data model 106 as it pertains to the present example embodiment. As shown in FIG. 4A, diagram 400 depicts nodes corresponding to respective devices in the enterprise IoT management system: (i) node 402, corresponding to data management sub-system 104, (ii) node 404, corresponding to sensor set 1 110, and (iii) node 406, corresponding to sensor set 2 112. Diagram 400 also includes edges indicating the relationships between the devices (while the edges are shown, their respective relationships are not shown, and are instead described herein). Edge 408, between node 402 and node 404, indicates that device management sub-system 104 sends instructions to sensor set 1 110 and that sensor set 1 110 sends collected data to device management sub-system 104. Similarly, edge 410, between node 402 and node 406, indicates that device management sub-system 104 sends instructions to sensor set 2 112 and that sensor set 2 112 sends collected data to device management sub-system 104. Edge 412, between node 404 and node 406, indicates that sensor set 1 110 and sensor set 2 112 are located in the same physical room.

A data model (such as data model 106) may be any digitized model that organizes information into nodes and edges, with the nodes representing types of information and the edges representing relationships between the types of information. While data model 106 of the present example embodiment certainly meets these requirements, it is anticipated that a wide variety of other types of models and/or configurations may be utilized by various embodiments of the present invention. As just an example, in other embodiments, such as embodiments discussed below in the Further Comments and/or Embodiment sub-section of this Detailed Description, data models may include: (i) ontologies; for example, an ontology representing a networked computer system such as networked computers system 100, an ontology representing a specialized computer system such as a Master Data Management (MDM) system or a supply chain management system, or an ontology that outlines a set of rules such as a regulatory scheme; and/or (ii) knowledge graphs; for example, a graph representing information about a specific set of topic(s) or a graph representing information known by a specific person/entity about a specific set of topics(s).

Processing proceeds to operation S260, where digital twin generation mod 360 generates a set of digital twin replicas based, at least in part, on the data model. In many cases, at least one digital twin replica of the set of digital twin replicas will correspond to a respective node of the data model. In the present embodiment, for example, two digital twin replicas are created: one that corresponds to node 404, corresponding to sensor set 1 110 affixed to the industrial fan, and one that corresponds to node 406, corresponding to sensor set 2 112 affixed to the light fixture. The digital twin replicas of the present embodiment are each configured to produce outputs that correspond to the outputs of their respective sensor sets. The formatting for these outputs is depicted in table view 450 of FIG. 4B, which includes table 452 depicting the output formatting for the digital twin corresponding to sensor set 1 110 (the “first digital twin”) and table 454 depicting the outputs formatting for the digital twin corresponding to sensor set 2 112 (the “second digital twin”). As shown in FIG. 4B, the first digital twin (and sensor set 1 110) produces rows of output having respective columns for the following values: (i) time, (ii) ambient temperature, (iii) ambient lighting, and (iv) fan power state. Similarly, the second digital twin (and sensor set 2 112) produces rows of output having respective columns for the following values: (i) time, (ii) ambient temperature, (iii) ambient lighting, and (iv) light power state. In various embodiments, a row of output may directly correspond to a row of a table used in the underlying computer system. For example, an embodiment that includes a master data management (MDM) system may include a digital twin that produces rows for a master data table of the MDM system.

A digital twin (such as the first digital twin and the second digital twin) may be any digital representation of an object or process, whether the object or process is physical, digital, or a combination thereof. For example, the digital twins of the present example embodiment, which respectively represent sensor set 1 110 and sensor set 2 112, are configured to produce the outputs of their respective sensor sets. That is, the first digital twin, when receiving one or more inputs, can produce outputs indicating the ambient temperature, ambient lighting, and fan power state for the industrial fan. Similarly, the second digital twin, when receiving one or more inputs, can produce outputs indicating the ambient temperature, ambient lighting, and light power state for the light fixture. A wide variety of other digital twin configurations may be utilized, such as those discussed below in the Further Comments and/or Embodiments sub-section of this Detailed Description, as well as others known in the art or to be developed in the future.

In some cases, the inputs received by the digital twins are simply incomplete sets of output data. For example, the first digital twin may receive, as input, an ambient temperature reading and an ambient lighting reading, and may use those readings to generate a fan power state so that a complete set of output data can be outputted. In other cases, the inputs received by the digital twins include data from other sources, for example, as indicated in the respective data model used in generating the digital twins.

The underlying architecture of the digital twins may vary widely based on the requirements of a particular embodiment. In the present example embodiment, for example, each digital twin includes neural architectures (i.e., neural networks) corresponding to respective columns of the digital twin’s output data. For example, the first digital twin includes a first neural network for the ambient temperature, a second neural network for the ambient lighting, and a third neural network for the fan power state. The second digital twin is configured similarly. Each neural network comprises a plurality of neurons that receive respective inputs and generate an output corresponding to the respective column of output data. The results from each neural network of a digital twin are then combined to form a single row of output for the digital twin.

For additional discussion of neural networks according to the various embodiments of the present invention, see the Further Comments and/or Embodiments sub-section of this Detailed Description, below.

Processing proceeds to operation S265, where digital twin execution mod 365 utilizes the set of digital twin replicas to generate simulated data corresponding to the types of information represented by the nodes of the data model. This data is referred to as “simulated” data because it is not data that is generated entirely by sensor set 1 110 and sensor set 2 112; instead, at least some of the data has been simulated by the digital twins created for the respective sensor sets.

In many cases, one or more intermediate steps exist between the execution of the set of digital twin replicas and the generation of the final simulated data. For example, in various embodiments, once a candidate row of simulated data is generated, the candidate row is evaluated to determine whether the data in the different columns of the row pass an objective reasonableness test - i.e., is it reasonable for the values of each column to be used in the same row? If the candidate row is determined to be reasonable, it is either used as the output of the digital twin or compared to other candidate rows in order to select an “optimal” candidate row, based on reasonableness and/or other factors. If the candidate row is determined not to be reasonable, portions of operation S265 are iteratively repeated until a reasonable candidate row is produced. Reasonableness may be calculated in any of a wide variety of ways including, for example, by using an objective function. In the present example embodiment, reasonableness is calculated using a loss minimization based objective function that compares the candidate row to benchmark data to see if the candidate row falls within a normal distribution of the benchmark data. Additional details regarding objective functions are provided below in the Further Comments and/or Embodiments sub-section of this Detailed Description.

Processing proceeds to operation S270, where data combination mod 370 combines the simulated data into a combined set of simulated data (the “combined set”) based, at least in part, on the data model. In the present example embodiment, the output from the first digital twin and the output from the second digital twin are combined and then analyzed based on data model 106. For example, because data model 106 and diagram 400 indicate that sensor set 1 110 and sensor set 2 112 are located in the same physical room (via edge 412), data combination mod 370 can compare the outputs of the first digital twin and the second digital twin to make sure they both include similar ambient temperature values and/or ambient lighting values at similar times, or that the respective ambient temperature values and ambient lighting values at certain times are reflected by the respective power states of the industrial fan and lighting fixture. In this way, because the combination of the simulated data into the combined set of simulated data is based on the industrial fan and the lighting fixture being in the same physical room, the combination is based, at least in part, on edge 412 of data model 106, with edge 412 representing the “same physical room” relationship between node 404 (corresponding to sensor set 1 110) and node 406 (corresponding to sensor set 2 112).

In operation S270, as in operation S265, if it is determined that certain sets of values should not be combined (i.e., the values are not reasonable to combine), additional iterations of operations S265 and S270 may be performed in order to produce acceptable results. The iterative nature of operations S265 and S270, where various columns and rows are compared to each other until they are able to be combined, is a particularly helpful benefit of using digital twin replicas that provides an improvement over conventional data simulation solutions. By using digital twins, various embodiments of the present invention are able to simulate values for multiple columns and/or rows in sequence prior to delivering results back to a requester such as data management sub-system 104.

Once the simulated data has been combined, the combined set may then be sent to data management sub-system 104 and/or elsewhere in networked computers system 100 for use in various data management tasks. For example, in the present example embodiment, the combined set is used as training data to train a neural network to better predict values of sensor set 1 110 and sensor set 2 112, and accordingly, performance of the industrial fan and light fixture. Because data model 106 is already provided in a graph-type structure, the combined set is arranged into a graph with a similar structure to data model 106 and used to train a graph neural network (GNN) via backpropagation or other means. After a number of training iterations, the GNN can then be used to predict future values of sensor set 1 110 and sensor set 2 112. For example, the GNN may: (i) receive, as input, a graph corresponding to the data model but with at least one incomplete type of information; and (ii) produce, as output, a complete version of the graph with the at least one incomplete type of information completed.

### III. Further Comments And/or Embodiments

Various embodiments of the present invention provide a system to simulate data using a network of digital twin replicas, where the topology of the network is determined by a data model such as a domain ontology or a knowledge graph. The data model may define, for example, the output of each node of the network, as well the relationships between the nodes. In various embodiments, each node corresponds to a respective digital twin or set of digital twins, where the digital twins do not have visibility over the larger network architecture. In various embodiments, the system also includes an evaluation component, which includes a downstream process and/or uses various metrics to evaluate the network after training.

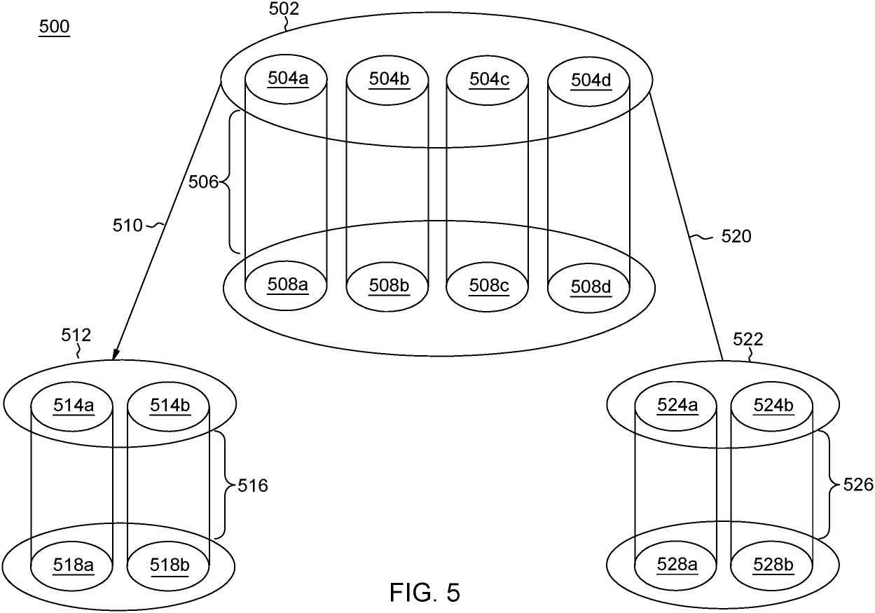

FIG. 5 is a diagram depicting an ontology according to an embodiment of the present invention. Ontology 500, as shown in FIG. 5, represents a Master Data Management (MDM) system having three agents (making the MDM system a “multi-agent” system): master data agent 502, transactional data agent 512, and behavioral data agent 522. In this embodiment, master data agent 502 produces outputs 504a, 504b, 504c, and 504d having “is a” relationships 506 to types 508a, 508b, 508c, and 508d, respectively. In this embodiment, type 508a is the type “person,” type 508b is the type “organization,” type 508c is the type “location,” and type 508d is the type “event.” Master data agent 502 has a “hasTransactions” relationship 510 to transactional data agent 512, where transactional data agent 512 produces outputs 514a and 514b having “is a” relationships 516 to types 518a and 518b, respectively. In this embodiment, type 518a is the type “invoice” and type 518b is the type “credit card.” Master data agent 502 has a “hasBehavior” relationship 520 to behavioral data agent 522, where behavioral data agent 522 produces outputs 524a and 524b having “is a” relationships 526 to types 528a and 528b, respectively. In this embodiment, type 528a is type “webpage user agent” and type 528b is type “survey.” Further, in this embodiment, master data agent 502, transactional data agent 512, and behavioral data agent 522 are each represented by a digital twin - referred to as the master data digital twin, the transactional data digital twin, and the behavioral data digital twin, respectively.

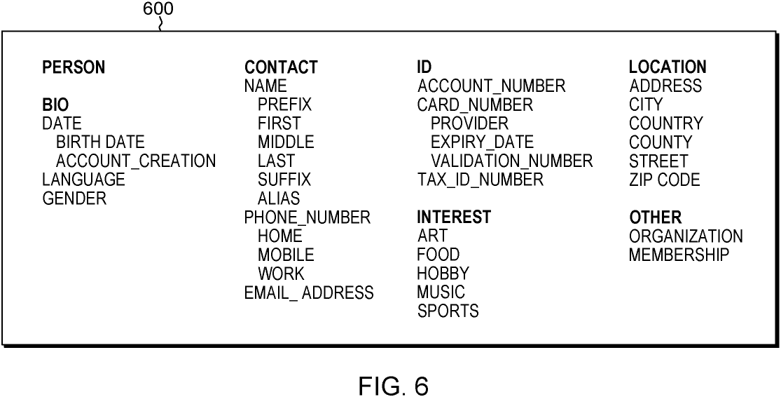

FIG. 6 is a diagram depicting additional details with respect to the ontology depicted in FIG. 5, according to an embodiment of the present invention. Ontological details 600, as shown in FIG. 6, include details about the “person” type (type 508a) used in producing output 504a by the master data digital twin that represents master data agent 502. These details may be utilized by one or more neural networks located within the master data digital twin or, for example, by one or more additional digital twins located within the master data digital twin, in order to simulate/generate data needed for producing the master data digital twin’s respective output(s). Generally speaking, a neural network may be adapted to produce a respective output based on one or more respective inputs. In various embodiments, each neural network located within a digital twin may correspond to a respective output of the digital twin; for example, outputs 504a, 504b, 504c, and 504d of the master data digital twin may each be produced by respective neural networks. Using ontological details 600 as an example, a neural network may be trained to: (i) receive, as input, an incomplete set of data corresponding to some, but not all, of the fields depicted in ontological details 600; and (ii) produce, as output, data corresponding to one or more of the remaining fields in ontological details 600, such that the data corresponding to the one or more of the remaining fields can be combined with the incomplete set of data to form a more complete output 504a.

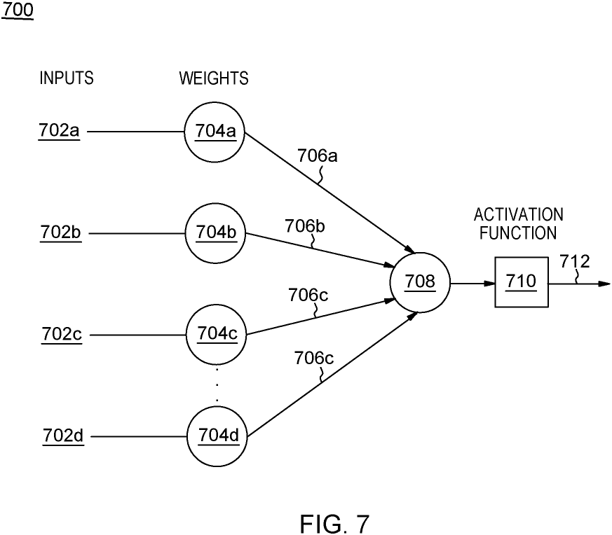

FIG. 7 depicts an example of a simple neural network constructed according to an embodiment of the present invention. As depicted in FIG. 7, neural network 700 includes inputs 702a, 702b, 702c, and 702d; weights 704a, 704b, 704c, and 704d; incoming edges 706a, 706b, 706c, and 706d; neuron 708, activation function 710, and outgoing edge 712. As shown in FIG. 7, neuron 708 receives inputs 702a, 702b, 702c, and 702d, weighted by weights 704a, 704b, 704c, and 704d (also referred to as “weighted neurons”), via incoming edges 706a, 706b, 706c, and 706d, respectively. Neuron 708 then generates output by applying activation function 710 to the weighted inputs (such that the output may be called a “function” of the inputs), directing the output to outgoing edge 712. Activation function 710 may include, for example, commonly used activation functions such as sigmoid, ReLU, and softmax.

In the embodiment depicted in FIG. 7, the neural network is adapted to perform a single task: it receives a particular set of task inputs (e.g., inputs 702a, 702b, 702c, and 702d) and produces, using an activation function (e.g., activation function 710), a single value/vector denoting the output of the single task. In other embodiments, other configurations may be used, such as configurations that produce multiple outputs from a single input or multiple outputs from multiple inputs, using one or more neural networks to do so, for example.

In various embodiments, a neural network such as neural network 700 may be contained within a digital twin that includes several such neural networks. For example, the digital twin representing behavioral data agent 522 may include two neural networks - one that generates output 524a and one that generates output 524b. In other embodiments, a digital twin may include a single neural network, producing a single output or multiple outputs, or may include multiple neural networks for one or more of the respective outputs, as may be required by a data model and/or other configuration parameters.

In various embodiments, by including one or more neural networks within the digital twin itself, the system is able to simulate the effects of various inputs to the neural networks, and even train the parameters of the neural networks (e.g., weights 704a, 704b, 704c, and 704d) based on those inputs. Training may occur via backpropagation or via any other training method known (or yet to be known) in the art.

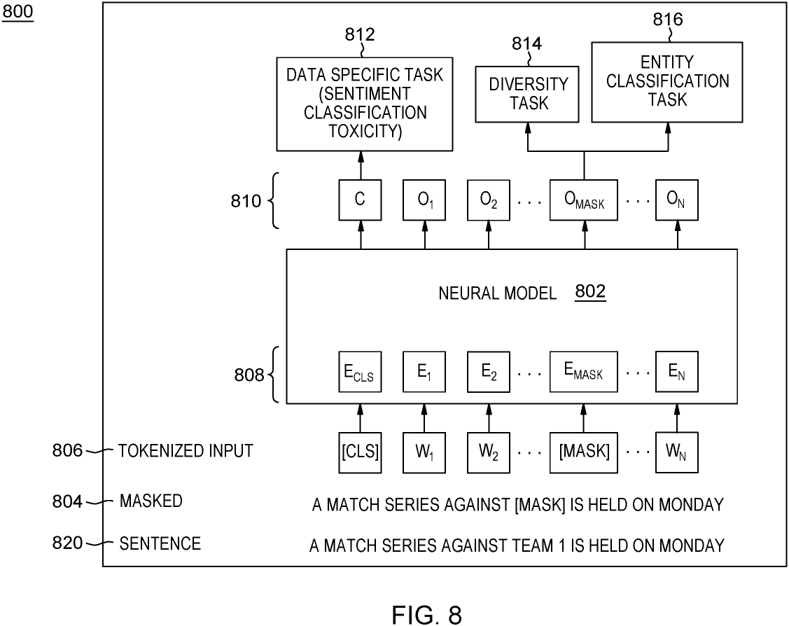

FIG. 8 depicts another example of a neural network (also referred to as a “neural model”) constructed according to an embodiment of the present invention. As depicted in FIG. 8 diagram 800 includes neural model 802. In this embodiment, model 802 is a language model, such as a Bidirectional Encoder Representations from Transformers (BERT) model, that receives a natural language sentence with one or more masked words as input and generates as output a prediction for the one or more masked words. For purposes of this embodiment, model 802 has been trained to generate output of the “organization” type (type 508b, see FIG. 5) used in producing output 504b by the master data digital twin. As shown in FIG. 8, masked sentence 804, “A match series against [MASK] is held on Monday,” is tokenized into tokenized input 806, where each word of masked sentence 804 is transformed into a respective token (where “CLS” stands for “classification,” “W” stands for “word,” and “MASK” stands for the masked word(s)). The tokens of tokenized input 806 are received by respective neurons 808 of model 802 (where “E” stands for “embedding”) and model 802 produces respective outputs 810 based on the tokens of tokenized input 806 (where “C” stands for “classification” and “O” stands for “output”). As shown in FIG. 8, outputs 810 include a token utilized by dataset specific task 812. For example, task 812 may be a sentiment classification/toxicity task, and may be based on a token of tokenized input 806 corresponding to a classification of the sentence. Outputs 810 also include an output corresponding to the one or more masked words, where the output corresponding to the one or more masked words is processed by diversity task 814 and entity classification task 816, resulting in an output (“Team 1”) that can be added to masked sentence 804 to form output sentence 820 (“A match series against Team 1 is held on Monday”).

In the embodiment depicted in FIG. 8, model 802 generates output 504b of the master data digital twin. In various embodiments, additional neural models similar to model 802 may be used to generate the other respective outputs (outputs 504a, 504c, and 504d) of the master data digital twin, such that each model produces a respective column for each row of output generated by the master data digital twin. Similar configurations may also be employed by the transactional data digital twin and the behavioral data digital twin, such that each digital twin produces respective rows for a respective table, with the columns of each row being generated by respective neural models.

Various embodiments of the present invention provide an objective function for the system, to evaluate the overall neural architecture performance. For example, with respect to the behavioral data digital twin that represents behavioral data agent 522, once candidates for outputs 524a and 524b are generated by their respective neural networks, the digital twin may apply an objective function to ensure that the candidates outputs 524a and 524b are within an expected range or distribution. In some cases, this involves utilizing a loss minimization based objective function to compare the candidate outputs to benchmark datasets.

For example, various embodiments of the present invention utilized gated neural networks, where either a single universal gate is used for all neurons, or different gates are used for different kinds of data. In these embodiments, the gate structure may be defined as: Ui(θi)=exp(-iθiP), where P is the input, θi is the gate parameter, and Ui(θi) is the gate output. In this example, objective function f(θ→) subject to minimization is defined as f(θ→)=〈θ→|L(x0,1~(z))|θ→〉, where L(x0,1~(z)) is the loss function defined as L(x0,1~(z))=1-1(z)1~(z), and where 1~(z) is the predicted value of the binary label.

As has been discussed, one use case of various embodiments of the present invention is in Master Data Management (MDM) systems. In such embodiments, it can be desirable to create a complete view of a customer represented in an MDM system by, for example, using Graph Neural Network (GNN) based models that fill the missing gaps or generate entire dimensions of data about an entity. However, in many cases, GNNs cannot be trained on the master data itself, for various privacy and/or data integration-related reasons. Instead, such models can be trained on simulated data and evaluated before the models are deployed or fine-tuned on real master data. This simulated data can be generated using digital twins.

In various embodiments, digital twins deployed in an MDM system may work in combination with various data virtualization technologies to unite various data sources and/or resolve missing information for various entities.

In various embodiments, data generators of an MDM system, traditionally configured to produce protected variables, can be adapted to generate digital twins, given that such data generators may already have access to information helpful in generated simulated data, such as configuration information and/or frequency distribution information related to various attributes of the MDM system.

Another use case of various embodiments of the present invention is in the field of supply chain management. Many supply chain management systems include a supply chain orchestration module (or “control tower”) that consumes various data about a supply chain - for example, data about a ship, data about a shipment, and/or data about past, present, and expected future events. In these systems, various embodiments of the present invention can be used to simulate that data in order to better inform metrics and/or predictions produced by the supply chain orchestration model. For example, digital twins can be utilized in a “what if” simulation to simulate different resolution scenarios using an optimization engine. The different resolutions can be compared and/or visualized in order to assist in decision making, and can be used to recommend the best corrective action.

Some other examples of supply chain management-related items that can be simulated using digital twins of various embodiments of the present invention include: (i) supply chain functions, such as inventory, logistics, and supply - used, for example, in combination with a supply chain insights platform and/or decision optimizer; and (ii) shipping containers and/or other shipment components, providing insight tools with up-to-the-minute status of containers which have historically represented a large gap in shipment status awareness.

In various embodiments, one or more of the following implementing technologies may be utilized in performing the various operations described above: (i) data generation tools that utilize recurrent neural networks (RNNs), language models, information extraction systems, and/or rule based decision making; (ii) text generation tools that utilize temporal point processes such as a Dirichlet Process and/or a Hawkes Process; (iii) tools that extract data from pseudonymized content using document structure and hypernymy; (iv) tools that generate bias free training data for link prediction; (v) tools that use joint learning for entity classification; (vi) tools that perform selective masking by sampling on related nodes from a GNN; and/or (vii) tools that perform classification of data entities using language models.

### IV. Definitions

Present invention: should not be taken as an absolute indication that the subject matter described by the term “present invention” is covered by either the claims as they are filed, or by the claims that may eventually issue after patent prosecution; while the term “present invention” is used to help the reader to get a general feel for which disclosures herein are believed to potentially be new, this understanding, as indicated by use of the term “present invention,” is tentative and provisional and subject to change over the course of patent prosecution as relevant information is developed and as the claims are potentially amended.

Embodiment: see definition of “present invention” above - similar cautions apply to the term “embodiment.”

and/or: inclusive or; for example, A, B “and/or” C means that at least one of A or B or C is true and applicable.

Including / include / includes: unless otherwise explicitly noted, means “including but not necessarily limited to.”

Module / Sub-Module: any set of hardware, firmware and/or software that operatively works to do some kind of function, without regard to whether the module is: (i) in a single local proximity; (ii) distributed over a wide area; (iii) in a single proximity within a larger piece of software code; (iv) located within a single piece of software code; (v) located in a single storage device, memory or medium; (vi) mechanically connected; (vii) electrically connected; and/or (viii) connected in data communication.

Computer: any device with significant data processing and/or machine readable instruction reading capabilities including, but not limited to: desktop computers, mainframe computers, laptop computers, field-programmable gate array (FPGA) based devices, smart phones, personal digital assistants (PDAs), body-mounted or inserted computers, embedded device style computers, application-specific integrated circuit (ASIC) based devices.

What is claimed is:

1. A computer-implemented method comprising:
receiving a data model, the data model including nodes representing types of information and edges representing relationships between the types of information;
generating a set of digital twin replicas, where a digital twin replica of the set of digital twin replicas corresponds to a respective node of the data model;
utilizing the set of digital twin replicas to generate simulated data corresponding to the types of information represented by the nodes of the data model; and
combining the simulated data generated by the set of digital twin replicas into a combined set of simulated data based, at least in part, on the edges of the data model.

2. The computer-implemented method of claim 1, wherein the digital twin replica of the set of digital twin replicas includes a neural architecture comprising a plurality of neurons.

3. The computer-implemented method of claim 2, wherein:
the digital twin replica of the set of digital twin replicas generates, as output, a row of simulated data; and
a neuron of the plurality of neurons generates simulated data corresponding to a respective column of the row of simulated data.

4. The computer-implemented method of claim 3, wherein:
the digital twin replica of the set of digital twin replicas corresponds to a respective table in a master data management (MDM) system; and
the row of simulated data corresponds to a row of the table.

5. The computer-implemented method of claim 3, further comprising evaluating the row of simulated data utilizing a loss minimization based objective function.

6. The computer-implemented method of claim 1, further comprising training a graph neural network utilizing the combined set of simulated data as training data.

7. The computer-implemented method of claim 6, further comprising:
receiving a graph corresponding to the data model, the graph including at least one incomplete type of information; and
utilizing the trained graph neural network to complete the at least one incomplete type of information.

8. A computer program product comprising one or more computer readable storage media and program instructions collectively stored on the one or more computer readable storage media, the program instructions executable by one or more computer processors to cause the one or more computer processors to perform a method comprising:
receiving a data model, the data model including nodes representing types of information and edges representing relationships between the types of information;
generating a set of digital twin replicas, where a digital twin replica of the set of digital twin replicas corresponds to a respective node of the data model;
utilizing the set of digital twin replicas to generate simulated data corresponding to the types of information represented by the nodes of the data model; and
combining the simulated data generated by the set of digital twin replicas into a combined set of simulated data based, at least in part, on the edges of the data model.

9. The computer program product of claim 8, wherein the digital twin replica of the set of digital twin replicas includes a neural architecture comprising a plurality of neurons.

10. The computer program product of claim 9, wherein:
the digital twin replica of the set of digital twin replicas generates, as output, a row of simulated data; and
a neuron of the plurality of neurons generates simulated data corresponding to a respective column of the row of simulated data.

11. The computer program product of claim 10, wherein:
the digital twin replica of the set of digital twin replicas corresponds to a respective table in a master data management (MDM) system; and
the row of simulated data corresponds to a row of the table.

12. The computer program product of claim 10, the method further comprising evaluating the row of simulated data utilizing a loss minimization based objective function.

13. The computer program product of claim 8, the method further comprising training a graph neural network utilizing the combined set of simulated data as training data.

14. The computer program product of claim 13, the method further comprising:
receiving a graph corresponding to the data model, the graph including at least one incomplete type of information; and
utilizing the trained graph neural network to complete the at least one incomplete type of information.

15. A computer system comprising:
one or more computer processors; and
one or more computer readable storage media; wherein:
the one or more computer processors are structured, located, connected and/or programmed to execute program instructions collectively stored on the one or more computer readable storage media; and
the program instructions, when executed by the one or more computer processors, cause the one or more computer processors to perform a method comprising:
receiving a data model, the data model including nodes representing types of information and edges representing relationships between the types of information;
generating a set of digital twin replicas, where a digital twin replica of the set of digital twin replicas corresponds to a respective node of the data model;
utilizing the set of digital twin replicas to generate simulated data corresponding to the types of information represented by the nodes of the data model; and
combining the simulated data generated by the set of digital twin replicas into a combined set of simulated data based, at least in part, on the edges of the data model.

16. The computer system of claim 15, wherein the digital twin replica of the set of digital twin replicas includes a neural architecture comprising a plurality of neurons.

17. The computer system of claim 16, wherein:
the digital twin replica of the set of digital twin replicas generates, as output, a row of simulated data; and
a neuron of the plurality of neurons generates simulated data corresponding to a respective column of the row of simulated data.

18. The computer system of claim 17, wherein:
the digital twin replica of the set of digital twin replicas corresponds to a respective table in a master data management (MDM) system; and
the row of simulated data corresponds to a row of the table.

19. The computer program product of claim 17, the method further comprising evaluating the row of simulated data utilizing a loss minimization based objective function.

20. The computer system of claim 15, the method further comprising:
training a graph neural network utilizing the combined set of simulated data as training data;
receiving a graph corresponding to the data model, the graph including at least one incomplete type of information; and
utilizing the trained graph neural network to complete the at least one incomplete type of information.
